(19) United States
(12) Patent Application Publication
(10) Pub. No.: US 2025/0112133 A1
(43) Pub. Date: Apr. 3, 2025

(54) PACKAGES WITH STEPPED CONDUCTIVE TERMINALS

(71) Applicant: TEXAS INSTRUMENTS INCORPORATED, Dallas, TX (US)

(72) Inventors: Huo Yun DUAN, Chengdu (CN); Tian Sheng CHEN, Chengdu (CN); Hang YAN, Chengdu (CN); Qin PENG, Chengdu (CN); Xiangrui LI, Chengdu (CN)

(21) Appl. No.: 18/478,087

(22) Filed: Sep. 29, 2023

(51) Int. Cl. H01L 23/495; H01L 21/56; H01L 23/00; H01L 23/31

(52) U.S. Cl. CPC H01L 23/49565; H01L 21/561; H01L 23/3107; H01L 23/49582; H01L 24/97; H01L 24/48; H01L 2224/48175; H01L 2224/97

(57) ABSTRACT

In examples, a method for manufacturing a package comprises coupling first and second semiconductor dies to a first surface of a conductive terminal; applying a dry film to a second surface of the conductive terminal opposite the first surface; removing a portion of the dry film contacting the second surface to form a dry film opening, the dry film opening having a linear, non-curved edge extending along a width of the conductive terminal; etching the second surface through the dry film opening; removing the dry film; plating the second surface; and sawing through the conductive terminal to form the package.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. Dies are then coupled to a lead frame and are covered by a mold compound, which is subsequently sawn to product a package.

### SUMMARY

In examples, a package comprises a die pad exposed to a bottom surface of the package, a semiconductor die coupled to the die pad, and a conductive terminal coupled to the semiconductor die. The conductive terminal comprises a first surface exposed to the bottom surface of the package, a second surface exposed to a lateral surface of the package that is orthogonal to the bottom surface of the package, and a third surface extending from the first surface toward the second surface. The third surface meets the first surface along an edge of the first surface that extends substantially parallel to the lateral surface of the package. The package also includes a mold compound member extending between the conductive terminal and a second conductive terminal, where the mold compound member includes a side surface that is orthogonal to the lateral and bottom surfaces of the package, and where at least a portion of the side surface is not covered by the conductive terminal.

In examples, a method for manufacturing a package comprises coupling first and second semiconductor dies to a first surface of a conductive terminal; applying a dry film to a second surface of the conductive terminal opposite the first surface; removing a portion of the dry film contacting the second surface to form a dry film opening, the dry film opening having a linear, non-curved edge extending along a width of the conductive terminal; etching the second surface through the dry film opening; removing the dry film; plating the second surface; and sawing through the conductive terminal to form the package.

### BRIEF DESCRIPTION OF THE DRAWINGS

FIG. 1A is a perspective view of a package having stepped conductive terminals, in accordance with various examples.

FIG. 1B is a top-down view of a package having stepped conductive terminals, in accordance with various examples.

FIG. 1C is a profile view of a package having stepped conductive terminals, in accordance with various examples.

FIG. 1D is a bottom-up view of a package having stepped conductive terminals, in accordance with various examples.

FIG. 1E is a profile, cross-sectional view of a package having stepped conductive terminals, in accordance with various examples.

FIG. 2 is a flow diagram of a method for manufacturing a semiconductor package having stepped conductive terminals, in accordance with various examples.

FIGS. 3A1-3F3 are a process flow of a method for manufacturing a semiconductor package having stepped conductive terminals, in accordance with various examples.

### DETAILED DESCRIPTION

Packages are generally coupled to printed circuit boards (PCBs) to enable communications with other electronic devices that are also coupled to the PCBs. A package may have conductive terminals, also sometimes known as pins or leads, that are exposed to a bottom and/or lateral surface of the package and that can be soldered to traces or pads on a PCB (e.g., in quad-flat no-lead (QFN) packages). Because the conductive terminals are electrically coupled to a die within the package, soldering the conductive terminals to the PCB provides an electrical pathway between the die and other electronic devices coupled to the PCB.

It is important to form strong, reliable solder connections between the conductive terminals and the PCB. Without these strong, reliable solder connections, the package can become at least partially detached from the PCB, impairing communications between the package and other devices coupled to the PCB. Such failures can be meaningful because they can result in entire electronic devices becoming non-functional.

Various techniques may be useful to gauge the integrity of the solder connections between conductive terminals and PCBs. In some applications, such as in automotive applications, solder connections may be visually inspected from above the package. The solder connections may be formed in specific ways to facilitate such visual inspections. For example, in some cases, a package may have multiple conductive terminals, and each conductive terminal may be exposed to both a bottom surface of the package and a lateral surface of the package, meaning that the conductive terminals straddles an edge of the package. Dimples may be formed in such conductive terminals, and these dimples are formed along the edge of the package, such that the dimple is a cavity that is exposed to both the bottom surface of the package and a lateral surface of the package. Applying solder at these dimples causes the solder to form a particular shape, called a solder fillet, which has a sloped shape. The slope is formed on the PCB and extends into the dimple, and it may be used to efficiently and visually evaluate the mechanical integrity of the solder connection to the conductive terminal. Such conductive terminals are sometimes called “wettable flanks.”

Packages having such conductive terminal dimples suffer from numerous technical challenges. First, to be adequately visible for optical inspection, the solder fillet must have a specified height, and to achieve this height, the dimple (and more specifically, the conductive terminal in which the dimple is formed) must have particular physical dimensions. But achieving these conductive terminal physical dimensions involves the use of expensive lead frames that must be etched multiple times, which is tedious, inefficient, and expensive. Second, the dimples are susceptible to mold flashing, in which material from within the package escapes (e.g., is extruded) externally, causing functional, mechanical, and cosmetic challenges. Third, the dimples are rounded in shape, leaving areas of thin metal in the conductive terminals, and these thin metal areas are susceptible to deformation. Fourth, the dimples are susceptible to burr formation, which require complex and challenging saw processes to remove. In summary, the dimples conventionally used in package conductive terminals for solder fillet formation are structurally flawed and produce numerous technical problems.

This disclosure describes various examples of packages having stepped conductive terminals that present technical solutions to the technical challenges described above. More specifically, the packages have conductive terminals that lack the aforementioned dimples and instead have step-like features that mitigate each of the challenges described above. For example, the stepped conductive terminals: do not require expensive lead frames; do not require multi-pass etching techniques; are not structurally susceptible to mold flashing; lack rounded shape and thus lack the thin metal areas that are susceptible to deformation; and are not susceptible to burr formation because etching to form the step-like features occurs after application of the mold compound. Examples of packages with stepped conductive terminals are now described with reference to the drawings.

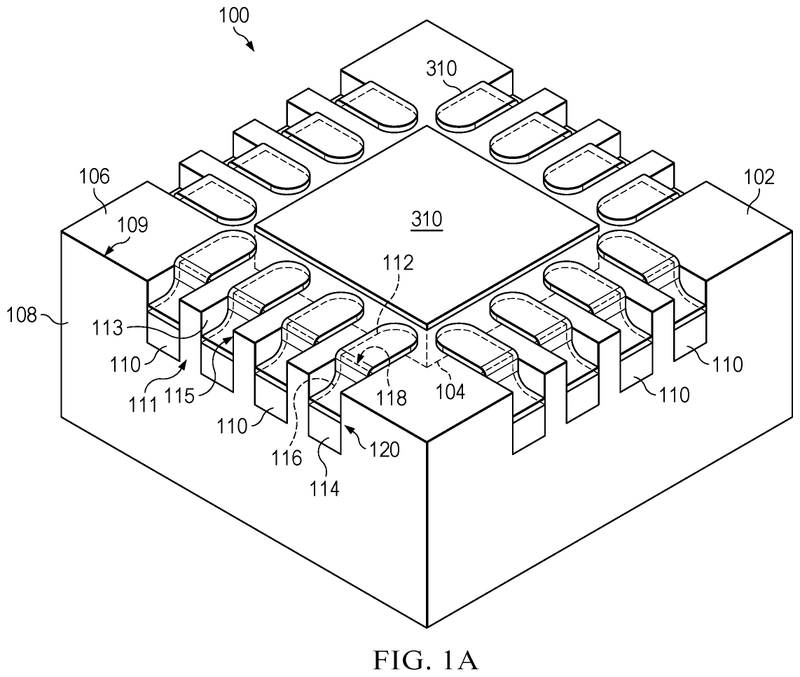

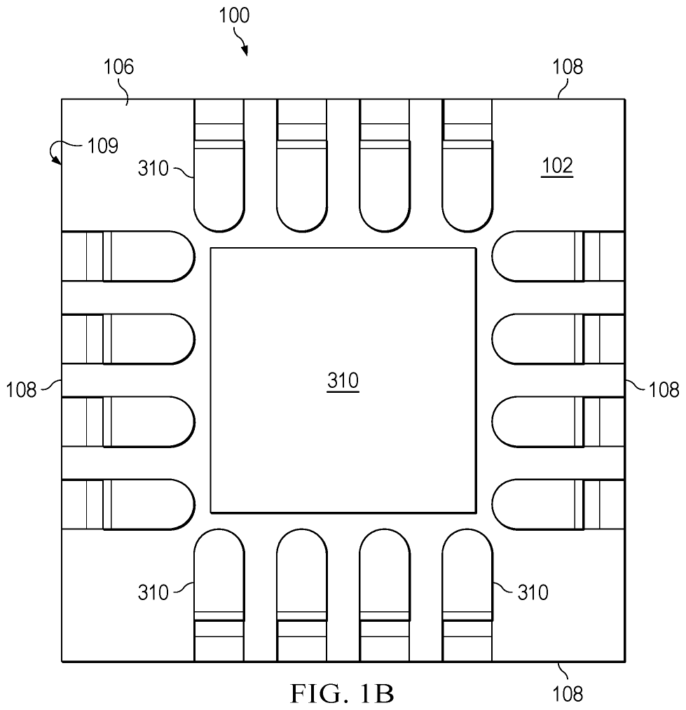

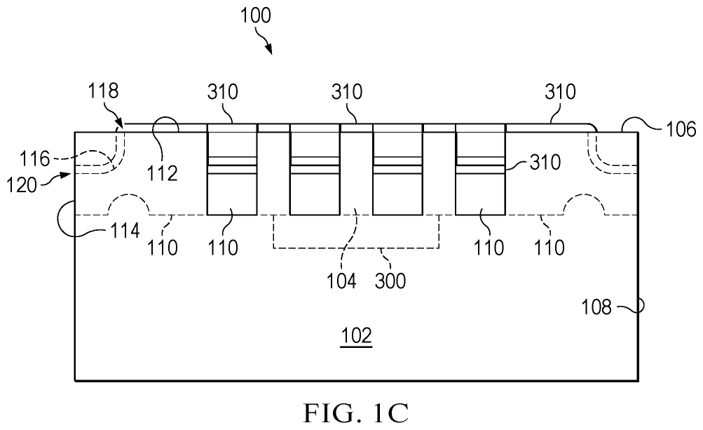

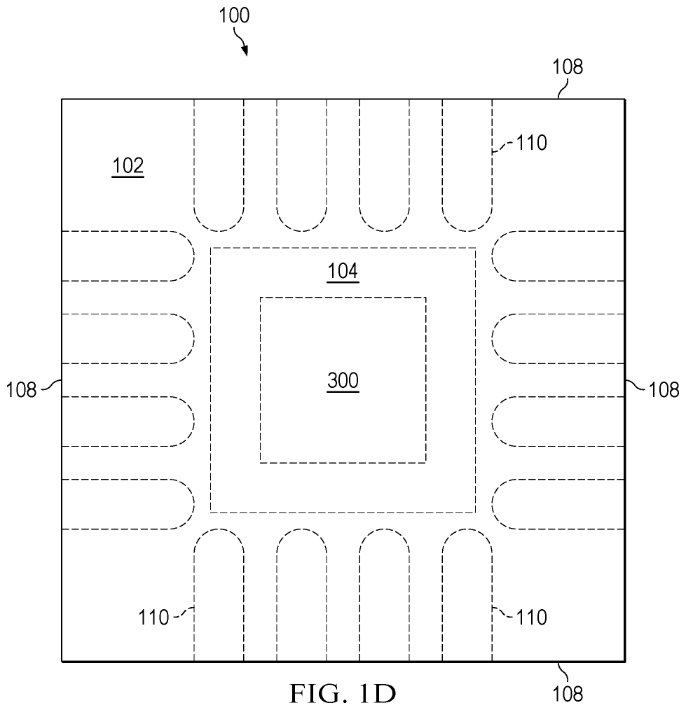

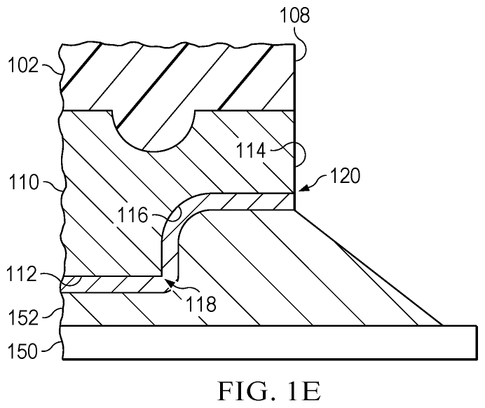

FIG. 1A is a perspective view of a package 100 having stepped conductive terminals, in accordance with various examples. The package 100 may be any suitable type of package, such as a quad flat no-lead (QFN) package. The package 100 includes a mold compound 102, a die pad 104 exposed from a bottom surface 106 of the mold compound 102, a lateral surface 108 that meets the bottom surface 106 at an edge 109 and that is approximately orthogonal to the bottom surface 106, multiple conductive terminals (e.g., leads or pins) 110, a terminal surface 112 exposed to and approximately flush with the bottom surface 106, a terminal surface 114 exposed to and approximately flush with the lateral surface 108, a terminal surface 116, an edge 118 where the terminal surfaces 112, 116 contact each other, and an edge 120 where the terminal surfaces 114 and 116 contact each other. The die pad 104 and portions of the conductive terminals 110 (excluding terminal surfaces 114) may be plated with tin plating 310. The various numerals used in FIG. 1A refer to the structures themselves and not to the tin plating 310.

As described, the terminal surface 112 is approximately flush with the bottom surface 106. The terminal surface 112 does not extend to the edge 109. Rather, the terminal surface 112 terminates at the edge 118, which is set back from the edge 109 by a distance ranging from 50 microns to 100 microns, with a distance lower than this range being disadvantageous because it unacceptably reduces solder wettability, and with a distance greater than this range being disadvantageous because it becomes unacceptably difficult to mount the package 100 to a PCB. In examples, the terminal surface 112 has a thumbnail shape, with an edge 118 extending linearly across the width of the conductive terminal 110/terminal surface 112, and with the remaining perimeter of the terminal surface 112 having a curved shape, as shown.

The terminal surface 114 is approximately flush with the lateral surface 108. The edge 120 of the terminal surface 114 does not extend to the edge 109. Rather, the terminal surface 114 terminates at the edge 120, which is set back from the edge 109 by a distance ranging from 75 microns to 190 microns, with a distance lower than this range being disadvantageous because it causes failure of automatic optical inspection (AOI) from a top-down view, and with a distance greater than this range being disadvantageous because the over-etching will result in terminal 110 surfaces with no plating, leaving the terminal 110 susceptible to damage. The terminal surface 114 has a rectangular shape with a perimeter having four linear (i.e., straight, not curved) edges. The height of the terminal surface 114 ranges from 10 microns to 125 microns, with a height below this range being disadvantageous because there will be no plating and thus the terminal 110 will be susceptible to damage, and with a height above this range being disadvantageous because it causes failure of AOI from a top-down view.

The edge 118 is linear, meaning that the edge 118 extends across the width of the conductive terminal 110 without significant curvature in the horizontal plane, substantially parallel to the edge 109, the lateral surface 108, and/or the edge 120. Each conductive terminal 110 lies between two segments of the bottom surface 106, and the edge 118 extends linearly between these two segments of the bottom surface 106, as shown. Similarly, the edge 120 is linear, meaning that the edge 120 extends substantially parallel to the edge 109, the surface 106, and/or the edge 118. Each conductive terminal 110 lies between two segments of the lateral surface 108, and the edge 120 extends linearly between these two segments of the lateral surface 108, as shown. The distance in the horizontal direction between the edges 118 and 120 ranges between 50 microns and 75 microns, with a distance below this range being disadvantageous because it unacceptable reduces solder wettability, and with a distance above this range being disadvantageous because it becomes unacceptably difficult to mount the package 100 to a PCB.

The terminal surface 116 extends between the edges 118 and 120. The terminal surface 116 is curved, with the degree of curvature depending on the etching technique used to form the terminal surface 116, as described below. The various structures and edges that form the conductive terminal 110 may give the conductive terminal 110 a stepped appearance, although the term “stepped” should not be interpreted as referring to any particular physical feature(s) or configuration(s).

Each conductive terminal 110 is seated within a cavity of the package 100. Within each cavity, just above the terminal surface 116, the walls of the cavity, which are composed of the mold compound 102, face each other along a line of sight. This line-of-sight between the mold compound 102 walls of each cavity extends parallel to the respective edges 118 and 120. The pitch between consecutive conductive terminals 110 is equal to or less than 0.5 mm. For example, a mold compound member 111 extends between two of the conductive terminals 110. The mold compound member 111 includes a side surface 113. The side surface 113 is orthogonal to the lateral surface 108 and bottom surface 106. The conductive terminal 110 closest to the side surface 113 does not cover all of the surface 113. Stated another way, at least a portion of the surface 113 is not covered by the conductive terminal 110 closest to the surface 113. The same mold compound member 111 may have a similar side surface (orthogonal to the lateral surface 108 and bottom surface 106) opposing the side surface 113, and that side surface is likewise at least partially not covered by the conductive terminal 110 closest to that side surface. The side surface 113 may face another side surface (orthogonal to the bottom surface 106 and lateral surface 108) of mold compound member 115 that is not covered by the conductive terminal 110 closest to that side surface of the mold compound member 115.

FIG. 1B is a top-down view of the package 100 having stepped conductive terminals, in accordance with various examples. FIG. 1C is a profile view of the package 100 having stepped conductive terminals, in accordance with various examples. FIG. 1D is a bottom-up view of the package 100 having stepped conductive terminals, in accordance with various examples. FIG. 1E is a profile, cross-sectional view of a portion of the package 100 having stepped conductive terminals, in accordance with various examples. FIG. 1E shows the conductive terminal 110 coupled to a PCB 150 by an example solder fillet 152.

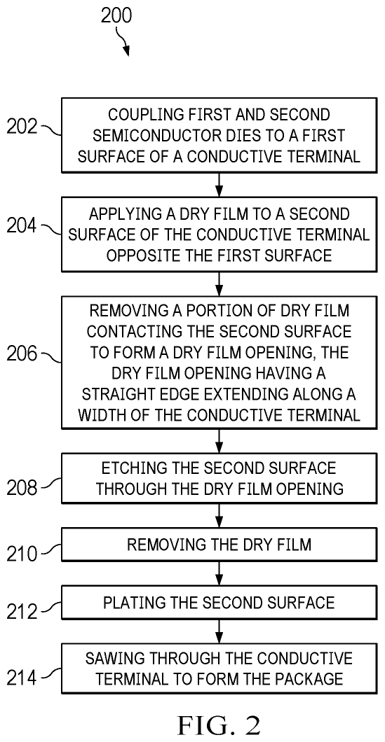

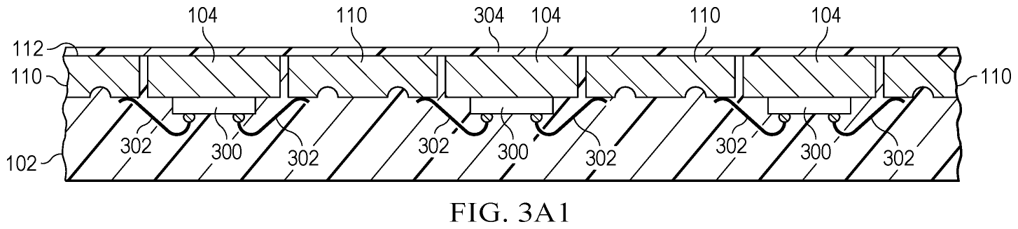

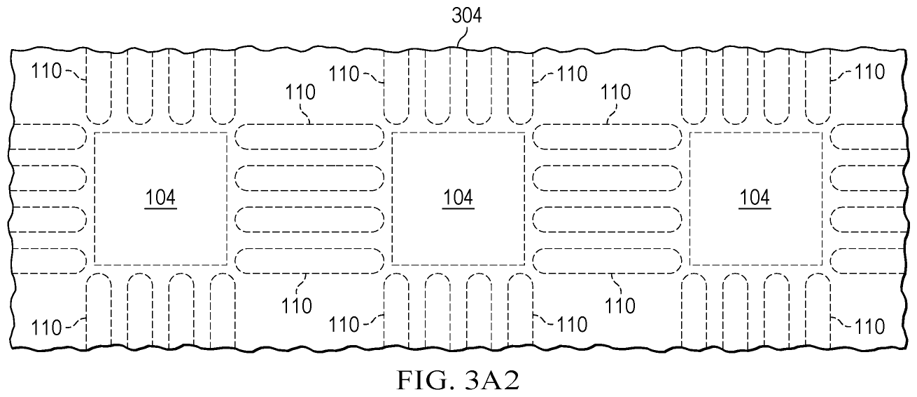

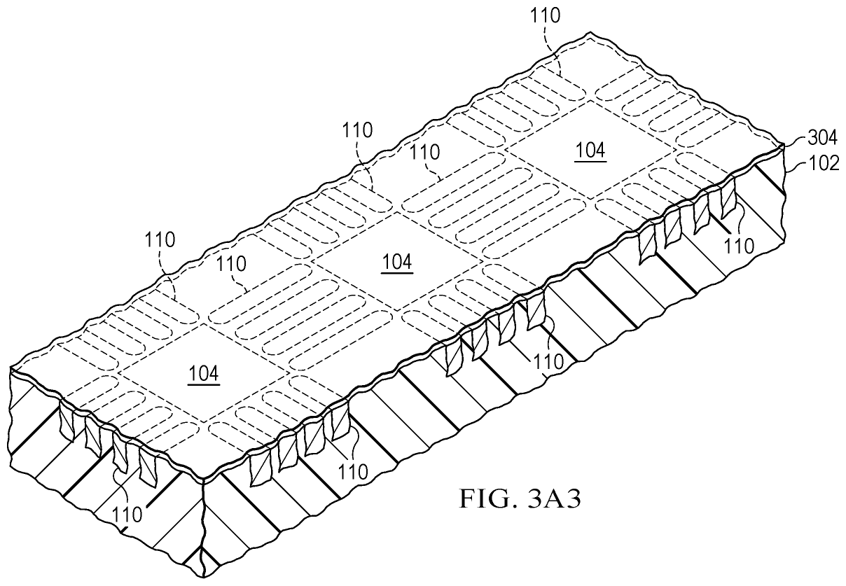

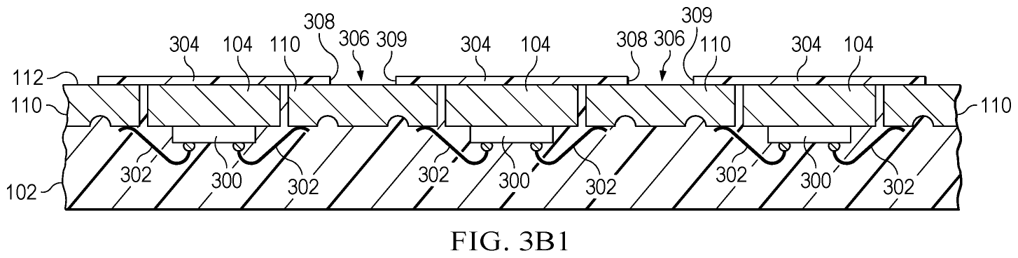

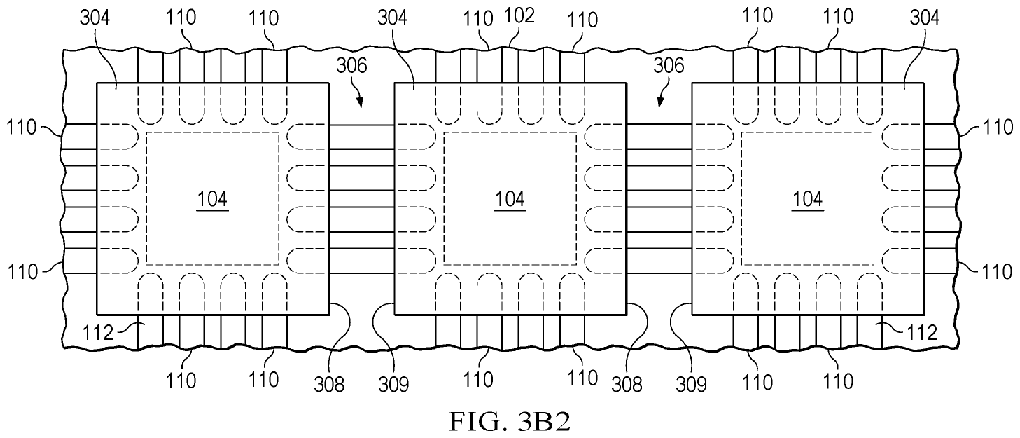

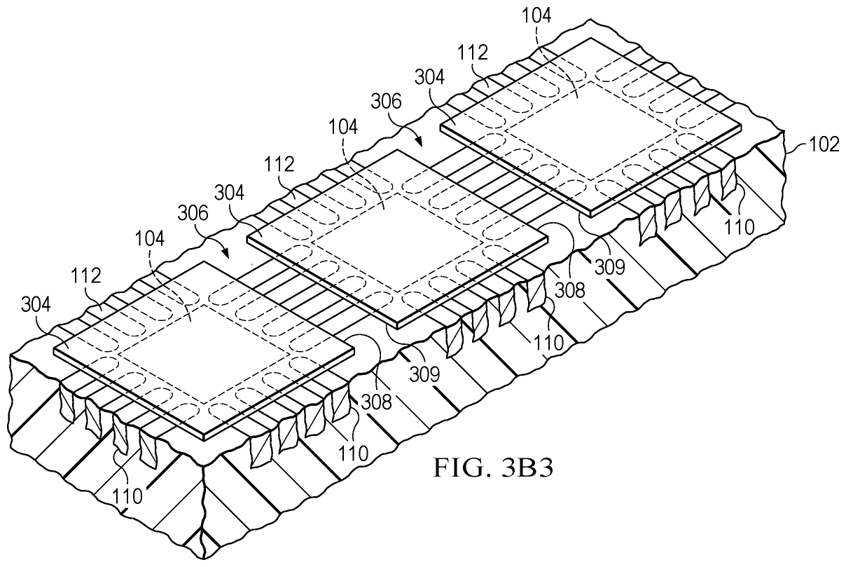

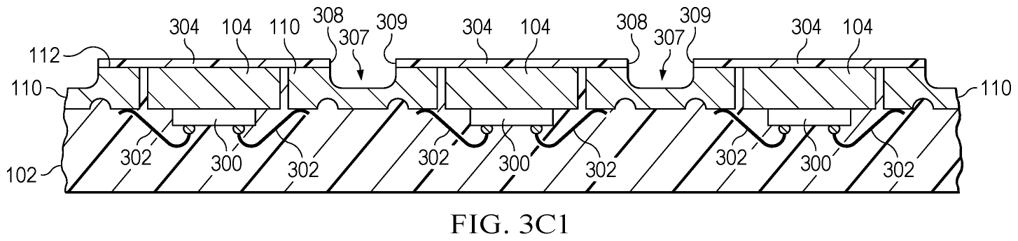

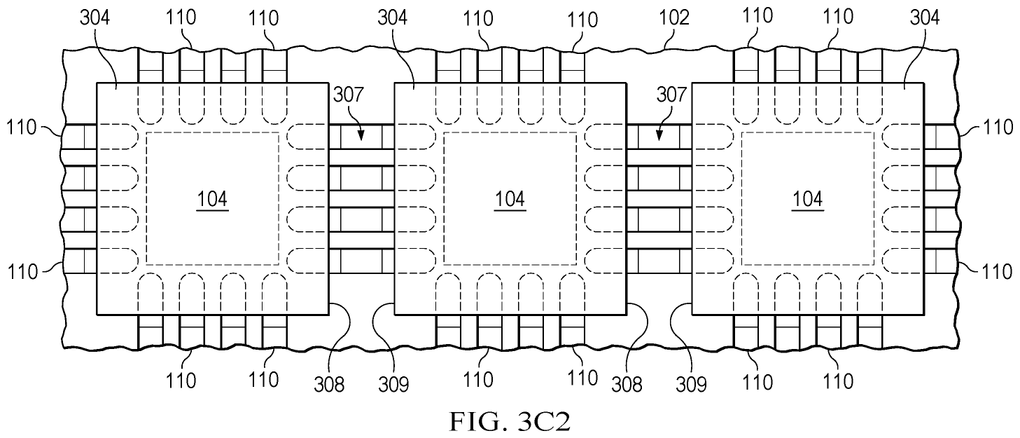

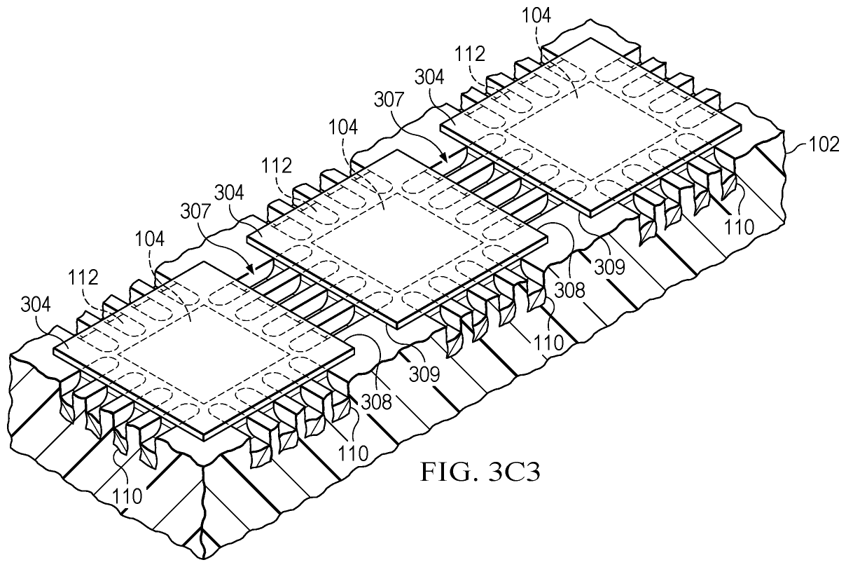

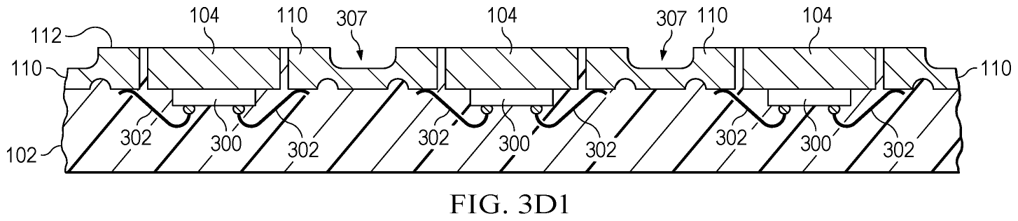

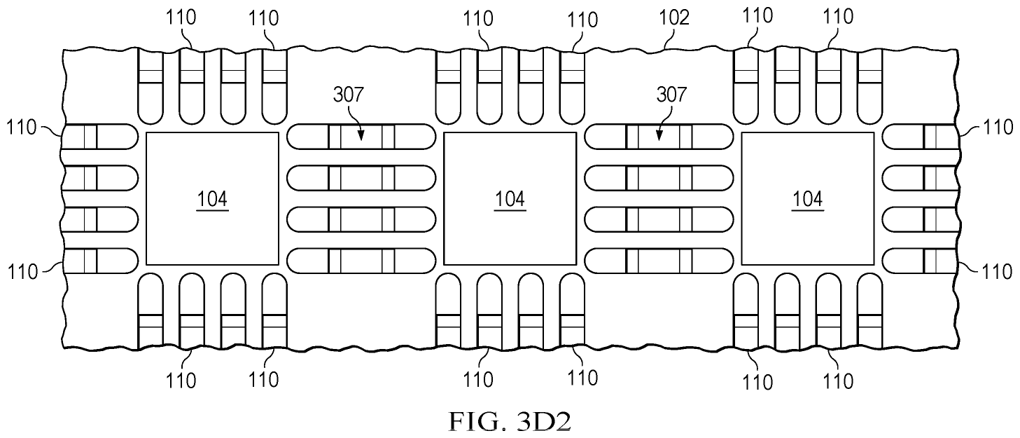

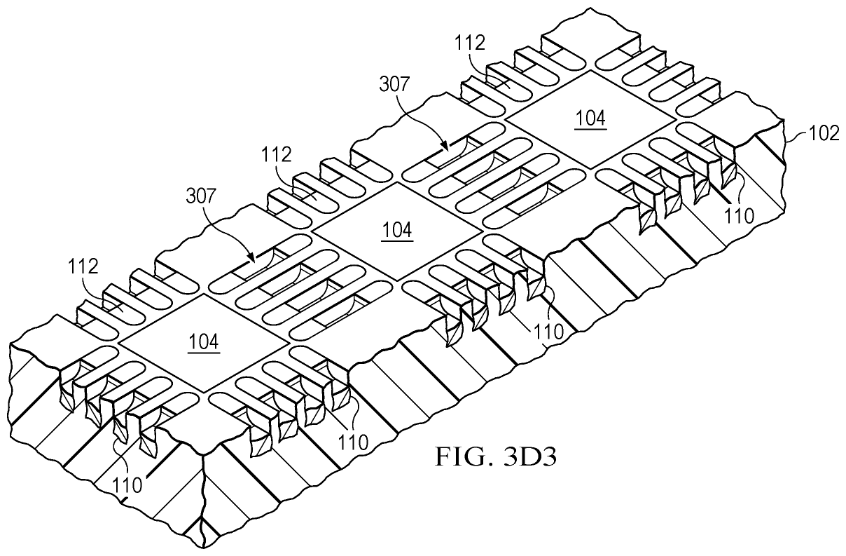

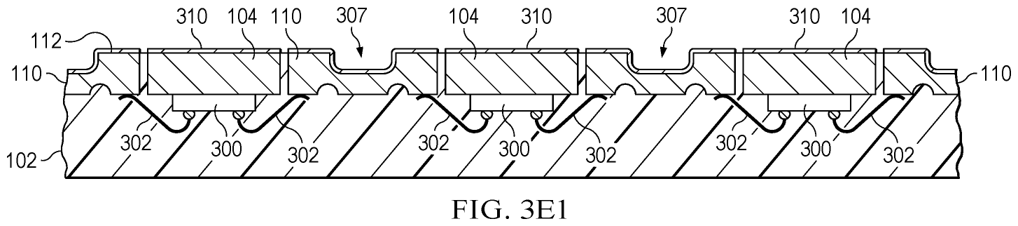

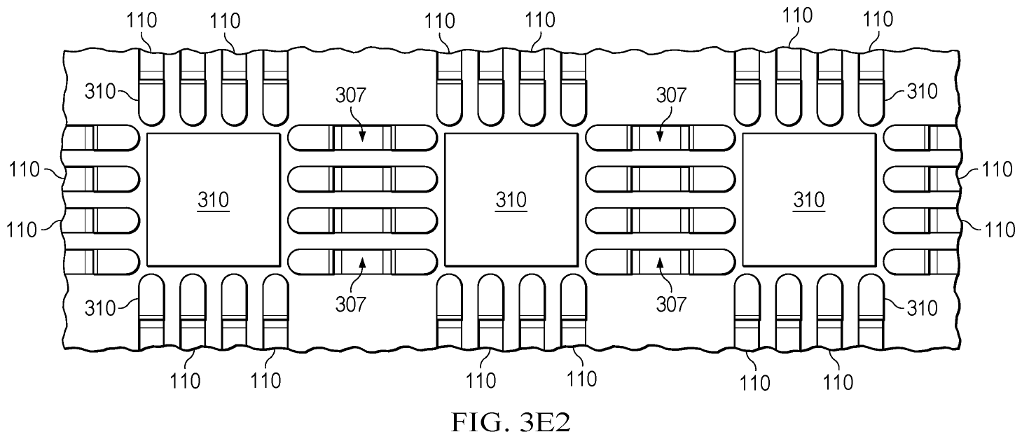

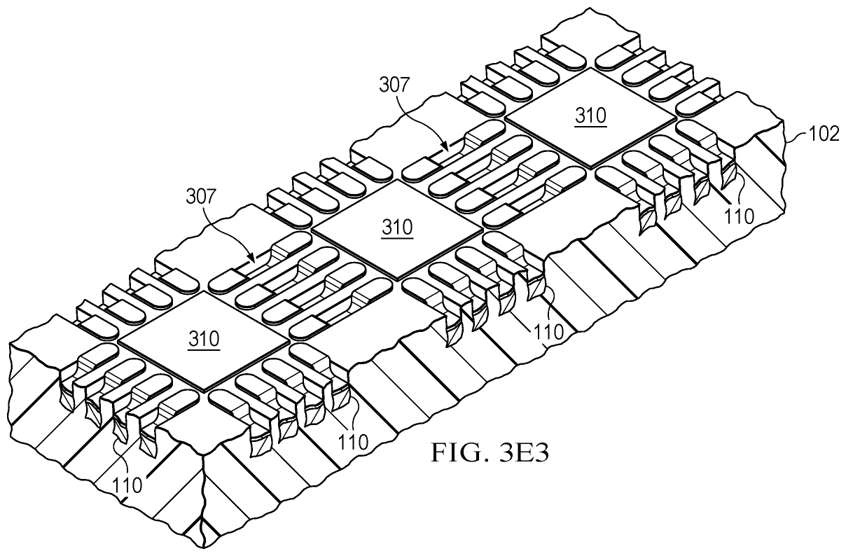

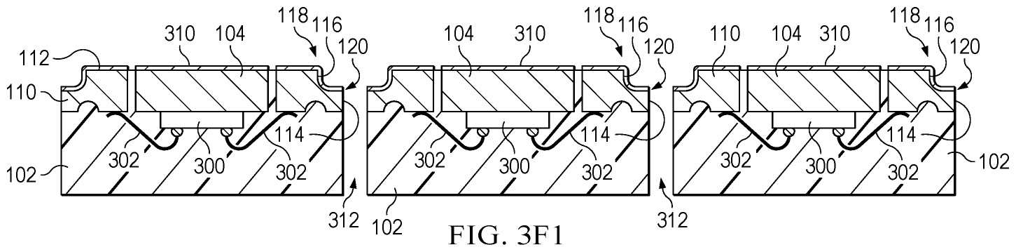

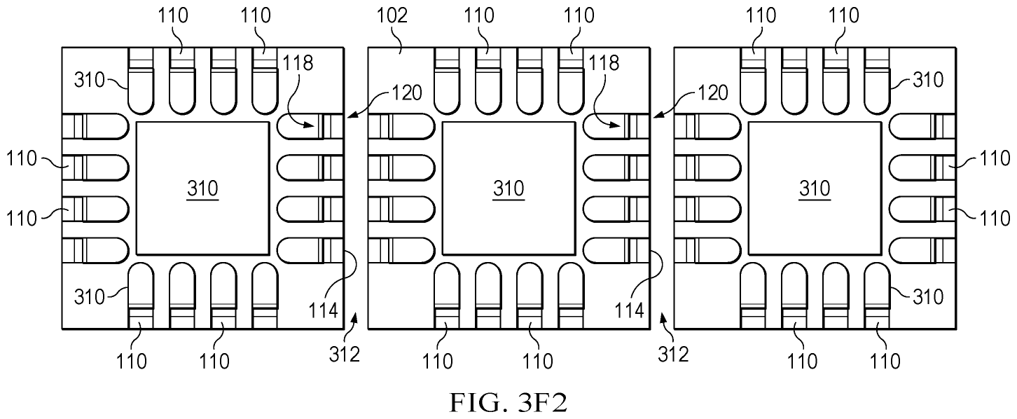

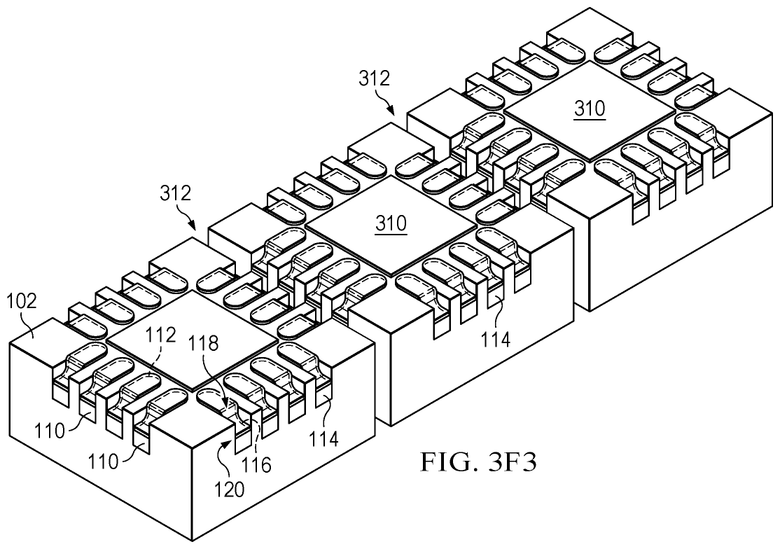

FIG. 2 is a flow diagram of a method 200 for manufacturing a semiconductor package (e.g., the package 100) having stepped conductive terminals, in accordance with various examples. FIGS. 3A1-3F3 are a process flow of a method for manufacturing a semiconductor package (e.g., package 100) having stepped conductive terminals, in accordance with various examples. Accordingly, FIGS. 2 and 3A1-3F3 are now described in parallel.

The method 200 includes coupling first and second semiconductor dies to a first surface of a conductive terminal (202). The mold compound 102 may also be applied. The method 200 also includes applying a dry film to a second surface of the conductive terminal opposite the first surface (204). FIG. 3A1 is a profile, cross-sectional view of multiple semiconductor dies 300 coupled to die pads 104. Bond wires 302 couple device sides of the semiconductor dies 300 in which circuitry is formed to first surfaces of the conductive terminals 110. A dry film 304 is applied to the second surfaces of the conductive terminals 110 and the surfaces of the die pads 104 that are opposite the semiconductor dies 300, as shown. The dry film 304 may be applied using any suitable technique, such as filming, printing, and embossing. The mold compound 102 is also applied to cover at least a portion of all of the structures shown in FIG. 3A1. FIG. 3A2 is a top-down view of the structure of FIG. 3A1, in accordance with various examples. FIG. 3A3 is a perspective view of the structure of FIG. 3A1, in accordance with various examples.

The method 200 includes removing a portion of the dry film contacting the second surface to form a dry film opening using any suitable technique, such as by laser (206). The dry film opening has a linear (i.e., straight, non-curved) edge extending along a width (e.g., at least a width) of the conductive terminal (206). FIG. 3B1 is a profile, cross-sectional view of the structure of FIG. 3A1, except that the dry film 304 has openings 306 formed therein. Each opening 306 is formed in an area of the dry film 304 that is in vertical alignment with a respective conductive terminal 110. The conductive terminals 110 shown in FIG. 3B1 have not yet been sawn, but after they are sawn, they will produce conductive terminals 110 that are incorporated into separate packages. More specifically, each opening 306 is centered over an approximate horizontal midpoint of a respective conductive terminal 110. Each opening 306 is defined by edges 308 and 309. It is critical that the edges 308 and 309 are linear (i.e., not curving), so that the edges 118 that are subsequently formed using the edges 308, 309 are also linear and have the specific physical features described above. FIG. 3B2 is a top-down view of the structure of FIG. 3B1, in accordance with examples. As shown, the opening 306 is in vertical alignment with multiple conductive terminals 110 (e.g., a row of conductive terminals 110), and thus the opening 306 spans the widths of multiple conductive terminals 110 that are in a row. FIG. 3B3 is a perspective view of the structure of FIG. 3B1, in accordance with various examples.

The method 200 includes etching the second surface through the dry film opening (208). FIG. 3C1 is a profile, cross-sectional view of the structure of FIG. 3B1, except that each of the conductive terminals 110 has been etched through respective openings 306 in the dry film 304. Any suitable etching technique may be useful, such as acid etching, chemical etching, electrolytic etching, laser etching, ultrasonic etching, physical etching, etc. The remaining dry film 304 protects areas of the structure of FIG. 3C1 that are not targeted for etching. The etchant may form a cavity 307 in each of the conductive terminals 110. The etching must be carefully controlled, as the manner in which each conductive terminal 110 is etched will affect the physical features of the terminal surface 116, the edge 120, and the terminal surface 114 of each conductive terminal 110. For example, the rate and/or depth of etch will affect the curvature of the cavity 307 (and thus, by extension, the curvature of the terminal surface 116 that will be later formed from the cavity 307 as described below) and the depth of the cavity 307 (and thus, by extension, the height of the terminal surface 116, the location of the edge 120, and the height of the terminal surface 114). The curvature of the cavity 307 is the same as the curvature of the terminal surface 116 as described above. The depth of the cavity 307 ranges from 0.075 mm to 0.19 mm, with a depth below this range being disadvantageous because AOI will fail, and with a depth above this range being disadvantageous because there will be no plating and thus the terminal will be more susceptible to damage. The horizontal width of the cavity 307 at the widest point ranges between 350 microns and 550 microns, with a width below this range being disadvantageous because it reduces solder wettability, and with a width above this range being disadvantageous because it becomes unacceptably difficult to mount the package to a PCB. FIG. 3C2 is a top-down view of the structure of FIG. 3C1, in accordance with various examples. FIG. 3C3 is a perspective view of the structure of FIG. 3C1, in accordance with various examples.

The method 200 includes removing (e.g., stripping) the dry film (210). FIG. 3D1 is a profile, cross-sectional view of the structure of FIG. 3C1, except that the dry film 304 has been removed, in accordance with various examples. FIG. 3D2 is a top-down view of the structure of FIG. 3D1, in accordance with various examples. FIG. 3D3 is a perspective view of the structure of FIG. 3D1, in accordance with various examples.

The method 200 includes plating the second surface (212). FIG. 3E1 is a profile, cross-sectional view of the structure of FIG. 3D1, except that the second surfaces of the conductive terminals 110, as well as the exposed surfaces of the die pads 104, are plated with a protective metal or alloy, such as tin plating 310. Other metals and alloys also may be used for plating, such as nickel palladium gold. The thickness of the tin plating 310 (or other plated layer) ranges from 7 microns to 20 microns, with a thickness below this range being disadvantageous because it will cause AOI failure, and with a thickness above this range being disadvantageous because it will result in burring challenges. FIG. 3E2 is a top-down view of the structure of FIG. 3E1, in accordance with various examples. FIG. 3E3 is a perspective view of the structure of FIG. 3E1, in accordance with various examples.

The method 200 includes sawing through the conductive terminal to form the package (214). FIG. 3F1 is a profile, cross-sectional view of the structure of FIG. 3E1, except that the structures have been sawn through the conductive terminals 110, for example, at the horizontal midpoints of the conductive terminals 110, as shown. Sawing forms gap 312. In this way, the structure of FIG. 3E1 is singulated into multiple, separate packages that are similar or identical to those described above with reference to FIGS. 1A-1E. The saw has a width ranging from 270 microns to 350 microns, with a saw width below this range being disadvantageous because the package size will be unacceptably large, and with a saw width above this range being disadvantageous because it may cut into vital components of the package. Singulation causes the terminal surfaces 114 to be revealed, and because they were unexposed pre-singulation, no plating (e.g., tin plating 310) is present on the terminal surfaces 114. FIG. 3F2 is a top-down view of the structure of FIG. 3F1, in accordance with various examples. FIG. 3F3 is a perspective view of the structure of FIG. 3F1, in accordance with various examples.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A method for manufacturing a package, comprising:
coupling first and second semiconductor dies to a first surface of a conductive terminal;
applying a dry film to a second surface of the conductive terminal opposite the first surface;
removing a portion of the dry film contacting the second surface to form a dry film opening, the dry film opening having a linear, non-curved edge extending along a width of the conductive terminal;
etching the second surface through the dry film opening;
removing the dry film;
plating the second surface; and
sawing through the conductive terminal to form the package.

2. The method of claim 1, wherein removing the portion of the dry film comprises using a laser to form a pattern on the dry film.

3. The method of claim 1, wherein etching the second surface comprises performing an acid etch.

4. The method of claim 1, wherein plating the second surface comprises plating tin on the second surface.

5. The method of claim 4, wherein sawing through the conductive terminal exposes a third surface of the conductive terminal, and wherein the third surface is not plated.

6. The method of claim 1, wherein the package is a quad flat no lead (QFN) package.

7. The method of claim 1, further comprising applying a mold compound, the mold compound including a mold compound member extending between the conductive terminal and a second conductive terminal, wherein the mold compound member includes a side surface that is orthogonal to lateral and bottom surfaces of the package, and wherein at least a portion of the side surface is not covered by the conductive terminal.

8. The method of claim 7, wherein the mold compound member includes a second side surface opposite the side surface, the second side surface orthogonal to the lateral and bottom surfaces off the package, and wherein at least a portion of the second side surface is not covered by the second conductive terminal.

9. A package, comprising:
a die pad exposed to a bottom surface of the package;
a semiconductor die coupled to the die pad;
a conductive terminal coupled to the semiconductor die, the conductive terminal comprising:
a first surface exposed to the bottom surface of the package;
a second surface exposed to a lateral surface of the package that is orthogonal to the bottom surface of the package; and
a third surface extending from the first surface toward the second surface, the third surface meeting the first surface along an edge of the first surface, the edge extending substantially parallel to the lateral surface of the package; and
a mold compound member extending between the conductive terminal and a second conductive terminal, wherein the mold compound member includes a side surface that is orthogonal to the lateral and bottom surfaces of the package, and wherein at least a portion of the side surface is not covered by the conductive terminal.

10. The package of claim 9, wherein the package is a quad flat no lead (QFN) package.

11. The package of claim 9, wherein the third surface is a curved surface.

12. The package of claim 9, wherein the first surface is substantially flush with the bottom surface.

13. The package of claim 9, wherein the second surface is substantially flush with the lateral surface.

14. The package of claim 9, wherein the first and third surfaces are plated with tin.

15. The package of claim 14, wherein the second surface is not plated with tin.

16. The package of claim 9, wherein the first and third surfaces are plated and the second surface is not plated.

17. The package of claim 9, further comprising a second mold compound member extending between the conductive terminal and a third conductive terminal, the conductive terminal positioned between the second and third conductive terminals, wherein:
the second mold compound member includes a second side surface that is orthogonal to the lateral and bottom surfaces of the package,
at least a portion of the second side surface is not covered by the conductive terminal, and
the side surface and the second side surface face each other.

18. The package of claim 9, wherein the edge is not curved.

19. A package, comprising:
a semiconductor die; and
a conductive terminal coupled to the semiconductor die, the conductive terminal comprising:
a first surface substantially flush with a bottom surface of the package;
a second surface substantially flush with a lateral surface of the package that is orthogonal to the bottom surface of the package; and
a curved surface extending from the first surface to the second surface, the curved surface meeting the first surface along a first edge and meeting the second surface along a second edge, the first and second edges parallel to the lateral surface.

20. The package of claim 19, wherein the first and second edges are not curved.

21. The package of claim 19, wherein the first and curved surfaces are plated with tin, and wherein the second surface is not plated with tin.

22. The package of claim 19, wherein the first and curved surfaces are plated and the second surface is not plated.

23. The package of claim 19, wherein the package is a quad flat no lead (QFN) package.
